(19) United States
(12) Patent Application Publication
(10) Pub. No.: US 2026/0029585 A1
(43) Pub. Date: Jan. 29, 2026

(54) LINEARLY INCREASING DEPTH GRATING

(71) Applicant: GOOGLE LLC, Mountain View, CA (US)

(72) Inventors: Wei Jin, Saratoga, CA (US); Thomas Mercier, Weston, FL (US)

(21) Appl. No.: 18/998,484

(22) PCT Filed: Jul. 26, 2022
(86) PCT No.: PCT/US2022/038282

§ 371 Date: Jan. 25, 2025

(51) Int. Cl. G02B 6/34; G02B 6/26; G02B 27/01; G03F 7/00; G03F 7/16

(52) U.S. Cl. CPC G02B 6/34; G02B 6/262; G02B 27/0172; G03F 7/0007; G03F 7/0035; G03F 7/16; G03F 7/70416; G02B 2027/0178

(57) ABSTRACT

A method includes disposing a hardmask coating atop a substrate and forming first openings through the hardmask coating. The method further includes forming a ramped resist coating atop the hardmask coating, the ramped resist coating sloping from a first end of the substrate to a second end of the substrate. The method even further includes etching a plurality of varying depth notches having varying depths within the substrate at locations corresponding to the first openings, the plurality of varying depth notches forming a substantially linearly increasing depth grating within the substrate.

### BACKGROUND

In a conventional wearable head-mounted display (HMD) for augmented reality (AR), light from an image source is coupled into a light guide substrate, generally referred to as a waveguide, by an input optical coupling such as an in-coupling grating (i.e., an “incoupler”), which can be formed on a surface, or multiple surfaces, of the substrate or disposed within the substrate. Once the light beams have been coupled into the waveguide, the light beams are “guided” through the substrate, typically by multiple instances of total internal reflection (TIR), to then be directed out of the waveguide by an output optical coupling (i.e., an “outcoupler”), which can also take the form of an optical grating. The light beams projected from the waveguide overlap at an eye relief distance from the waveguide forming an exit pupil within which a virtual image generated by the image source can be viewed by the user of the HMD.

In some HMDs, the incoupler is an optical grating, which can be produced by physically forming grooves or other surface features on a surface of a waveguide, or volume features within the waveguide substrate. The overall efficiency of a grating depends on various application-specific parameters such as wavelength, polarization, and angle of incidence of the incoming light. The efficiency of a grating is also influenced by the grating design parameters, such as the distance between adjacent grating features, grating width, thickness of the grating region, and the angle the gratings form with the substrate.

### SUMMARY OF EMBODIMENTS

In some embodiments of a method, the method includes disposing a hardmask coating atop a substrate and forming first openings through the hardmask coating. The method further includes forming a ramped resist coating atop the hardmask coating, the ramped resist coating sloping from a first end of the substrate to a second end of the substrate. The method even further includes etching a plurality of varying depth notches having varying depths within the substrate at locations corresponding to the first openings, the plurality of varying depth notches forming a substantially linearly increasing depth grating within the substrate.

In some embodiments of the method, the forming the first openings includes disposing a high contrast resist atop the hardmask coating, forming second openings through the high contrast resist via a first lithography, and removing the high contrast resist via etching.

In some embodiments of the method, the first lithography includes one of E beam lithography, Deep Ultraviolet (DUV) lithography, and nanoimprint lithography.

In some embodiments of the method, the ramped resist coating is a low contrast resist coating and forming the ramped resist coating includes applying a second lithography to the low contrast resist coating.

In some embodiments of the method, the second lithography is a grayscale lithography that exposes the low contrast resist coating with a spatially modulated dose of lithography to form the ramped resist coating, the spatially modulated dose linearly increasing in dosage from a first end of the low contrast resist coating to a second end of the low contrast resist coating.

In some embodiments of the method, the method further includes removing the hardmask coating via etching.

In some embodiments of the method, the substrate is a silicon dioxide-based material.

In some embodiments of another method, another method includes disposing a hardmask coating atop a substrate and forming first openings through the hardmask coating. The method further includes etching a plurality of varying depth notches having varying depths within the substrate at locations corresponding to the first openings, the plurality of varying depth notches forming a substantially linearly increasing depth grating within the substrate.

In some embodiments of another method, the forming the first openings includes disposing a high contrast resist atop the hardmask coating, forming second openings through the high contrast resist via a first lithography, and removing the high contrast resist via etching.

In some embodiments of another method, the first lithography includes one of E beam lithography, Deep Ultraviolet (DUV) lithography, and nanoimprint lithography.

In some embodiments of another method, another method further includes forming a ramped low-contrast resist coating atop the hardmask coating, the ramped resist coating sloping from a first end of the substrate to a second end of the substrate, by applying a second lithography to a low contrast resist coating to form the ramped low-contrast resist coating.

In some embodiments of another method, the second lithography is a grayscale lithography that exposes the low contrast resist coating with a spatially modulated dose of lithography to form the ramped low-contrast resist coating, the spatially modulated dose linearly increasing in dosage from a first end of the low-contrast resist coating to a second end of the low contrast resist coating.

In some embodiments of another method, the method further includes removing the hardmask coating via etching.

In some embodiments of another method, the substrate is a silicon dioxide-based material.

In some embodiments of a grating structure, the grating structure includes a substantially linearly increasing depth grating disposed within a substrate, the substantially linearly increasing depth grating including a plurality of varying depth notches within the substrate.

In some embodiments of the grating structure, the substantially linearly increasing depth grating is formed via a method including disposing a hardmask coating atop a substrate and forming first openings through the hardmask coating. The method further includes forming a ramped resist coating atop the hardmask coating, the ramped resist coating sloping from a first end of the substrate to a second end of the substrate. The method even further includes etching a plurality of varying depth notches having varying depths within the substrate at locations corresponding to the first openings, the plurality of varying depth notches forming a substantially linearly increasing depth grating within the substrate.

In some embodiments of the grating structure, the forming the first openings includes disposing a high contrast resist atop the hardmask coating, forming second openings through the high contrast resist via a first lithography, and removing the high contrast resist via etching.

In some embodiments of the grating structure, the ramped resist coating is a low contrast resist coating and the forming the ramped resist coating includes applying a second lithography to the low contrast resist coating to form the ramped resist coating.

In some embodiments of the grating structure, the second lithography is a grayscale lithography that exposes the low contrast resist coating with a spatially modulated dose of lithography to form the ramped resist coating, the spatially modulated dose linearly increasing in dosage from a first end of the low contrast resist coating to a second end of the low contrast resist coating.

In some embodiments of the grating structure, the method further includes removing the hardmask coating via etching.

In some embodiments of the grating structure, the substrate is a silicon dioxide-based material.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 shows an example display system having a waveguide utilizing a linearly increasing depth grating, in accordance with at least one configuration disclosed herein.

FIG. 2 illustrates a block diagram of a laser projection system that projects laser light representing images onto the eye of a user via a display system, such as the display system of FIG. 1, utilizing the linearly increasing depth grating, in accordance with at least one configuration disclosed herein.

FIG. 3 shows an example of light propagation within a waveguide of a laser projection system, such as the laser projection system of FIG. 2, including the linearly increasing depth grating, in accordance with at least one configuration disclosed herein.

FIG. 4-1 shows an example substrate into which a linearly increasing depth grating is formed, in accordance with some embodiments.

FIG. 4-2 illustrates an example structure after the substrate illustrated in FIG. 4-1 is processed, in accordance with some embodiments.

FIG. 4-3 shows another example structure after the structure illustrated in FIG. 4-2 is processed, in accordance with some embodiments.

FIG. 4-4 illustrates yet another example structure after the structure illustrated in

FIG. 4-3 is processed, in accordance with some embodiments.

FIG. 4-5 shows even yet another example structure after the substrate illustrated in FIG. 4-4 is processed, in accordance with some embodiments.

FIG. 4-6 illustrates one more example structure after the structure illustrated in FIG. 4-5 is processed, in accordance with some embodiments.

FIG. 4-7 shows one more example structure after the structure illustrated in FIG. 4-6 is processed, in accordance with some embodiments.

FIG. 4-8 illustrates an additional example structure after the substrate illustrated in FIG. 4-7 is processed, thereby forming the linearly increasing depth grating, in accordance with some embodiments.

FIG. 5 shows a method flow of an example method to form the linearly increasing depth grating shown in FIGS. 2-4, in accordance with some embodiments.

FIG. 6 illustrates a method flow of an example intermediate method to form openings through a hardmask coating prior to forming the linearly increasing depth grating with the method shown in FIG. 5, in accordance with some embodiments.

### DETAILED DESCRIPTION

In some HMDs, typical gratings can vary in-depth into a substrate, formed in a stepped pattern. This varied depth stepped grating is typically produced via a fabrication process for each step. A problem with using a fabrication process for each step, respectively, is that performing multiple fabrication processes to produce the stepped grating is time-consuming. Conventional nanoimprint molding utilizes a multi-level lithography process to create a multi-level discrete depth stepped grating structure. The complexity, cost, and product lead-time of this typical process increases significantly as the number of steps increases.

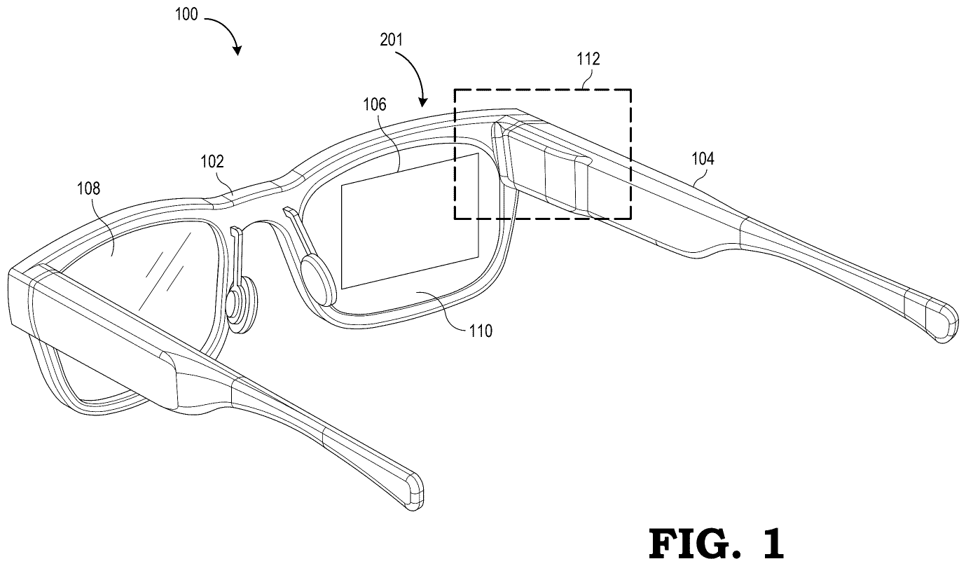

FIGS. 1-6 illustrate systems and techniques of providing for a substantially linearly increasing depth grating within a substrate. Such a substantially linearly increasing depth grating is preferred for waveguide applications. Instead of being fabricated via multiple fabrication steps for each step, respectively, of the typical stepped grating, an entirety of the substantially linearly increasing depth grating is fabricated via a single fabrication process as compared to a conventional fabrication process for each step of the typical stepped grating. While the disclosed systems and techniques are described with respect to an example display system, it will be appreciated that present disclosure is not limited to implementation in this particular display system, but instead may be implemented in any of a variety of display systems using the guidelines provided herein.

FIG. 1 illustrates an example display system 100 having a support structure 102 that includes an arm 104, which houses a laser projection system configured to project images toward the eye of a user, such that the user perceives the projected images as being displayed in a field of view (FOV) area 106 of a display at one or both of lens elements 108, 110. In the depicted embodiment, the display system 100 is a wearable head-mounted display (HMD) that includes a support structure 102 configured to be worn on the head of a user and has a general shape and appearance of an eyeglasses frame. The support structure 102 contains or otherwise includes various components to facilitate the projection of such images toward the eye of the user, such as a laser projector, an optical scanner, and a waveguide. In some embodiments, the support structure 102 further includes various sensors, such as one or more front-facing cameras, rear-facing cameras, other light sensors, motion sensors, accelerometers, and the like. The support structure 102 further can include one or more radio frequency (RF) interfaces or other wireless interfaces, such as a Bluetooth™ interface, a WiFi interface, and the like. Further, in some embodiments, the support structure 102 includes one or more batteries or other portable power sources for supplying power to the electrical components of the display system 100. In some embodiments, some or all of these components of the display system 100 are fully or partially contained within an inner volume of support structure 102, such as within the arm 104 in region 112 of the support structure 102. It should be noted that while an example form factor is depicted, it will be appreciated that in other embodiments the display system 100 may have a different shape and appearance from the eyeglasses frame depicted in FIG. 1.

One or both of the lens elements 108, 110 are used by the display system 100 to provide an augmented reality (AR) or mixed reality (MR) display in which rendered graphical content can be superimposed over or otherwise provided in conjunction with a real-world view as perceived by the user through the lens elements 108, 110. For example, laser light used to form a perceptible image or series of images may be projected by a laser projector of the display system 100 onto the eye of the user via a series of optical elements, such as a waveguide formed at least partially in the corresponding lens element, one or more scan mirrors, and one or more optical relays. One or both of the lens elements 108, 110 thus include at least a portion of a waveguide that routes display light received by an incoupler, or multiple incouplers, of the waveguide to an outcoupler of the waveguide, which outputs the display light toward an eye of a user of the display system 100. The display light is modulated and projected onto the eye of the user such that the user perceives the display light as an image. In addition, each of the lens elements 108, 110 is sufficiently transparent to allow a user to see through the lens elements to provide a field of view of the user's real-world environment such that the image appears superimposed over at least a portion of the real-world environment.

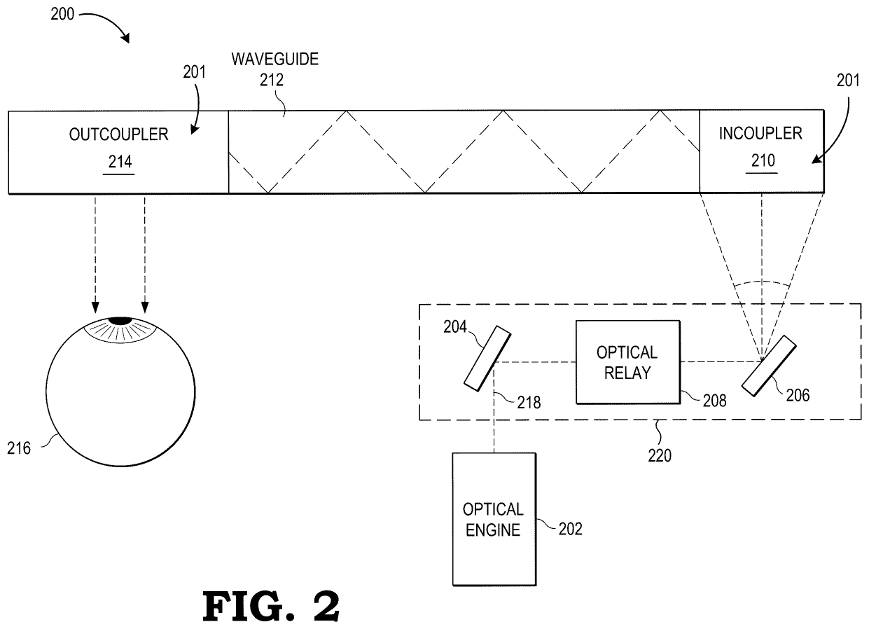

FIG. 2 illustrates a block diagram of a laser projection system 200 that projects laser light representing images onto the eye 216 of a user via a waveguide, such as that illustrated in FIG. 1. The laser projection system 200 includes an optical engine 202, an optical scanner 220, and a waveguide 212. In some embodiments, the laser projection system 200 is implemented in a wearable heads-up display or other display systems.

The optical engine 202 includes one or more laser light sources configured to generate and output laser light (e.g., visible laser light such as red, blue, and green laser light and/or non-visible laser light such as infrared laser light). In some embodiments, the optical engine 202 is coupled to a controller or driver (not shown), which controls the timing of emission of laser light from the laser light sources of the optical engine 202 (e.g., in accordance with instructions received by the controller or driver from a computer processor coupled thereto) to modulate the laser light 218 to be perceived as images when output to the retina of the eye 216 of the user.

The optical scanner 220 includes a first scan mirror 204, a second scan mirror 206, and an optical relay 208. One or both of the scan mirrors 204 and 206 may be MEMS mirrors, in some embodiments. For example, the scan mirror 204 and the scan mirror 206 are MEMS mirrors that are driven by respective actuation voltages to oscillate during active operation of the laser projection system 200, causing the scan mirrors 204 and 206 to scan the laser light 218. Oscillation of the scan mirror 204 causes laser light 218 output by the optical engine 202 to be scanned through the optical relay 208 and across a surface of the second scan mirror 206. The second scan mirror 206 scans the laser light 218 received from the scan mirror 204 toward an incoupler 210 of the waveguide 212. In some embodiments, the scan mirror 204 oscillates along a first scanning axis, such that the laser light 218 is scanned in only one dimension (i.e., in a line) across the surface of the second scan mirror 206. In some embodiments, the scan mirror 206 oscillates along a second scan axis that is perpendicular to the first scan axis.

The waveguide 212 of the laser projection system 200 includes the incoupler 210 and the outcoupler 214. The term “waveguide,” as used herein, will be understood to mean a combiner using total internal reflection (TIR), or via a combination of TIR, specialized filters, and/or reflective surfaces, to transfer light from an incoupler to an outcoupler. For display applications, the light may be a collimated image, and the waveguide transfers and replicates the collimated image to the eye. In general, the terms “incoupler” and “outcoupler” will be understood to refer to any type of optical grating structure, including, but not limited to, diffraction gratings, slanted gratings, blazed gratings, holograms, holographic optical elements (e.g., optical elements using one or more holograms), volume diffraction gratings, volume holograms, surface relief diffraction gratings, and/or surface relief holograms. In some embodiments, a given incoupler or outcoupler is configured as a transmissive diffraction grating that causes the incoupler or outcoupler to transmit light and to apply designed optical function(s) to the light during the transmission. In some embodiments, a given incoupler or outcoupler is a reflective diffraction grating that causes the incoupler or outcoupler to reflect light and to apply designed optical function(s) to the light during the reflection. In the present example, the laser light 218 received at the incoupler 210 is relayed to the outcoupler 214 via the waveguide 212 using TIR. The laser light 218 is then output to the eye 216 of a user via the outcoupler 214.

In some embodiments, incoupler 210 is a substantially rectangular feature configured to receive the laser light 218 and direct the laser light 218 into the waveguide 212. The incoupler 210 may be defined by a small dimension (i.e., width) and a long dimension (i.e., length). In an embodiment, the optical relay 208 is a line-scan optical relay that receives the laser light 218 scanned in a first dimension by the first scan mirror (e.g., the first dimension corresponding to the small dimension of the incoupler 210), routes the laser light 218 to the second scan mirror 206, and introduces a convergence to the laser light 218 in the first dimension. The second scan mirror 206 receives the converging laser light 218 and scans the laser light 218 in a second dimension, the second dimension corresponding to the long dimension of the incoupler 210 of the waveguide 212. The second scan mirror may cause the laser light 218 to converge to a focal line along the second dimension. In some embodiments, the incoupler 210 is positioned at or near the focal line downstream from the second scan mirror 206 such that the second scan mirror 206 scans the laser light 218 as a line over the incoupler 210. In some embodiments, at least one of the incoupler 210 and the outcoupler 214 includes a linearly increasing depth grating 201, the details of which are described below. The linearity of the linearly increasing depth grating 201 can vary slightly (+−10%) in accordance with fabrication variations used to produce the linearly increasing depth grating 201, such that the linearly increasing depth grating 201 is, in some embodiments, a substantially linearly increasing depth grating 201.

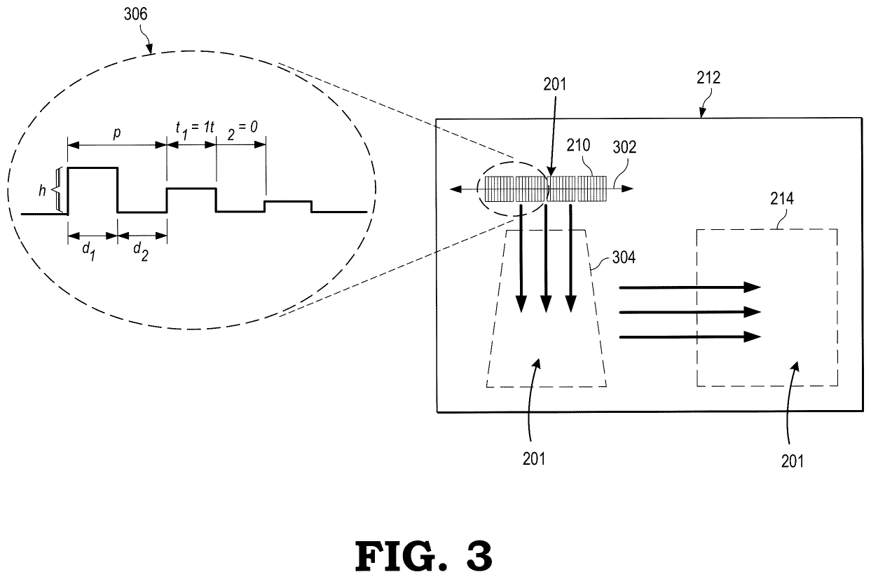

FIG. 3 shows an example of light propagation within the waveguide 212 of the laser projection system 200 of FIG. 2. As shown, light is received via incoupler 210, scanned along the axis 302, directed into an exit pupil expander 304, and then routed to the outcoupler 214 to be output from the waveguide 212 (e.g., toward the eye of the user). In some embodiments, the exit pupil expander 304 expands one or more dimensions of the eyebox of an HMD that includes the laser projection system 200 (e.g., with respect to what the dimensions of the eyebox of the HMD would be without the exit pupil expander 304). In some embodiments, the incoupler 210 and the exit pupil expander 304 each include respective one-dimensional diffraction gratings (i.e., diffraction gratings that extend along one dimension).

It should be understood that FIG. 3 shows a substantially ideal case in which incoupler 210 directs light straight down (with respect to the presently illustrated view) in a first direction that is perpendicular to the scanning axis 302, and the exit pupil expander 304 directs light to the right (with respect to the presently illustrated view) in a second direction that is perpendicular to the first direction. While not shown in the present example, it should be understood that, in some embodiments, the first direction in which the incoupler 210 directs light is slightly or substantially diagonal, rather than exactly perpendicular, with respect to the scanning axis 302. In some embodiments, the exit pupil expander 304 includes the linearly increasing depth grating 201.

Also shown in FIG. 3 is a cross-section 306 of incoupler 210 illustrating features of the linearly increasing depth grating 201 that can be configured to tune the efficiency of incoupler 210, and in some embodiments at least one of the outcoupler 214 and exit pupil expander 304 utilizing the linearly increasing depth grating 201 having a same cross-section 306. The period p of the grating is shown having two regions, with transmittances t1=1 and t2=0 and widths d1 and d2, respectively. The grating period is constant p=d1+d2, but the relative widths d1, d2 of the two regions may vary. A fill factor parameter x can be defined such that d1=xp and d2=(1−x)p. In addition, while the profile shape of the grating features in cross-section 306 is generally shown as being square or rectangular with a height h, the shape can be modified based on the wavelength of light that incoupler 210 is intended to receive. For example, in some embodiments, the shape of the grating features is triangular, rather than square, to create a more “saw-toothed” profile. In some embodiments, incoupler 210 is configured as a grating with a constant period but different fill factors, heights, and slant angles based on the desired efficiency of the respective incoupler 210 or the desired efficiency of a region of the respective incoupler 210.

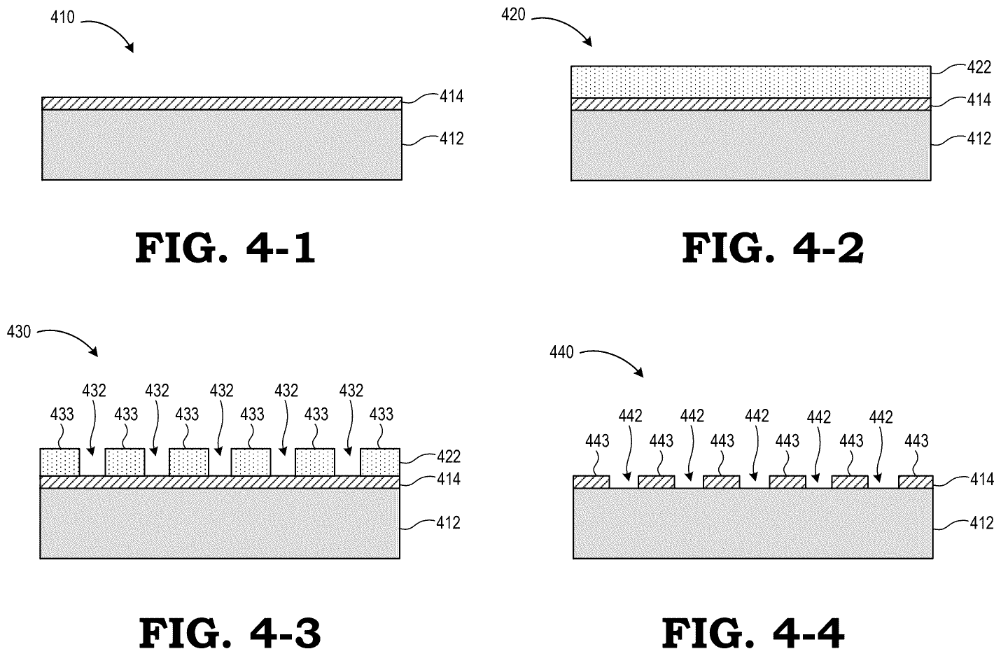

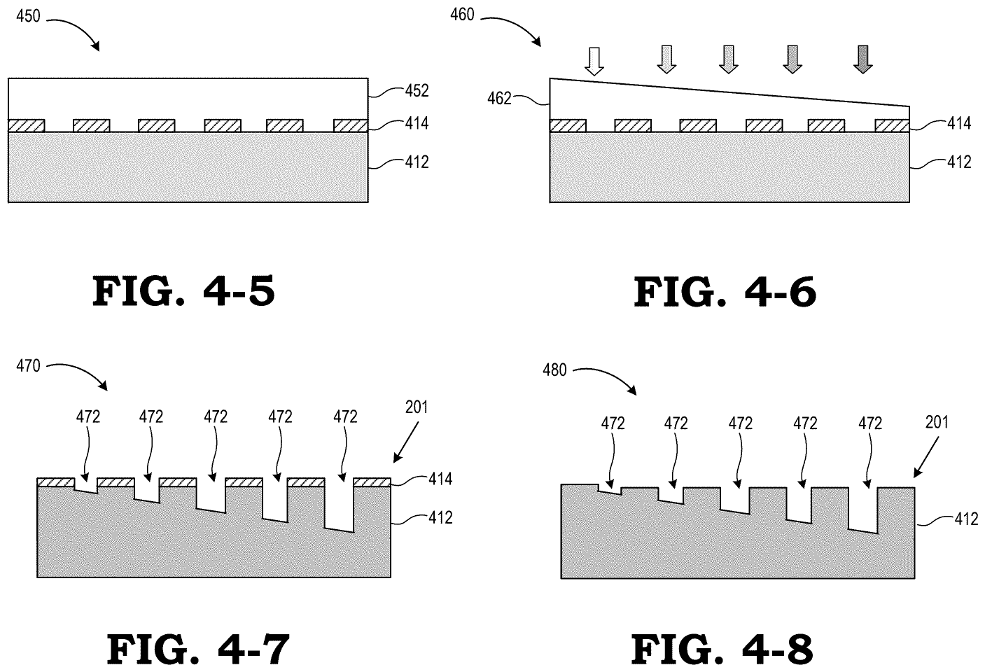

FIGS. 4-1-4-8 shows an example fabrication process to form the linearly increasing depth grating 201, shown in FIGS. 2 and 3. The linearly increasing depth grating 201 is fabricated via a single fabrication process, instead of typical multiple fabrication processes for steps, respectively, of a typical grating. FIG. 4-1 shows a cross-sectional view 410 of the linearly increasing depth grating 201 in early stages of fabrication. A hardmask coating 414 is disposed atop an entirety of a substrate 412. The hardmask coating 414 is a material used in semiconductor processing as an etch mask instead of a polymer or other organic “soft” resist material. The hardmask coating 414 is metal or dielectric, such as silicon nitride (SiN), in some embodiments, with silicon based masks, such as silicon dioxide or silicon carbide, possible (e.g., SiOCH (carbon doped hydrogenated silicon oxide)). The metal hardmask can include titanium nitride, tantalum nitride, chromium (Cr), and Chromium oxide. In some embodiments, the substrate 412 is a silicon dioxide-based material, such as quartz. In some other embodiments, other materials are possible for the substrate 412, such as a pure silicon substrate, that allows for the linearly increasing depth grating 201 to be formed therein.

FIG. 4-2 illustrates a cross-sectional view 420 of another layer that is disposed atop the hardmask coating 414. A high contrast resist 422 is disposed atop an entirety of the hardmask coating 414 in some embodiments. FIG. 4-3 illustrates a cross-sectional view 430 after lithography has been applied to the structure shown in FIG. 4-2. In some embodiments, the lithography includes one of E beam lithography, Deep Ultraviolet (DUV) lithography, and nanoimprint lithography. The lithography is applied to the high contrast resist 422 to produce openings 432 through the high contrast resist 422. Lithography is a process by which light (typically ultraviolet light) that includes a desired pattern to be formed into the high contrast resist 422 is projected onto or applied to the high contrast resist 422. The high contrast resist 422 breaks down when exposed to this light. In the cross-sectional view 430, the high contrast resist 422 breaks down and thereby removed in the areas of the openings 432. The openings 432 result in blocks of high contrast resist 433 being disposed on either side of the openings 432. The patterning of the openings 432 and blocks 422 define grating lateral dimensions (e.g., the pitch or critical dimension (CD) linewidth). The number of the openings 432 also defines the number of grating notches, as discussed with respect to FIG. 4-7. FIG. 4-3 shows five (5) notches, although in some embodiments more or fewer openings 432 are utilized.

FIG. 4-4 illustrates a cross-sectional view of a structure 440 after etching has been applied to the structure shown in FIG. 4-3. In some embodiments, this etching is a dry etching (e.g. via plasma), although in other embodiments chemical or wet etching (e.g., via a type of acid depending upon the material being etched) is also possible. Etching is a process by which portions of a film are selectively removed to create a design within the film, such as the high contrast resist 422. This etching is applied to the structure shown in FIG. 4-3 to remove the high contrast resist 422. This etching is applied to the structure shown in FIG. 4-3 to also produce openings 442 through the hardmask coating 414. The openings 442 result in blocks of hardmask coating 443 being disposed on either side of the openings 442.

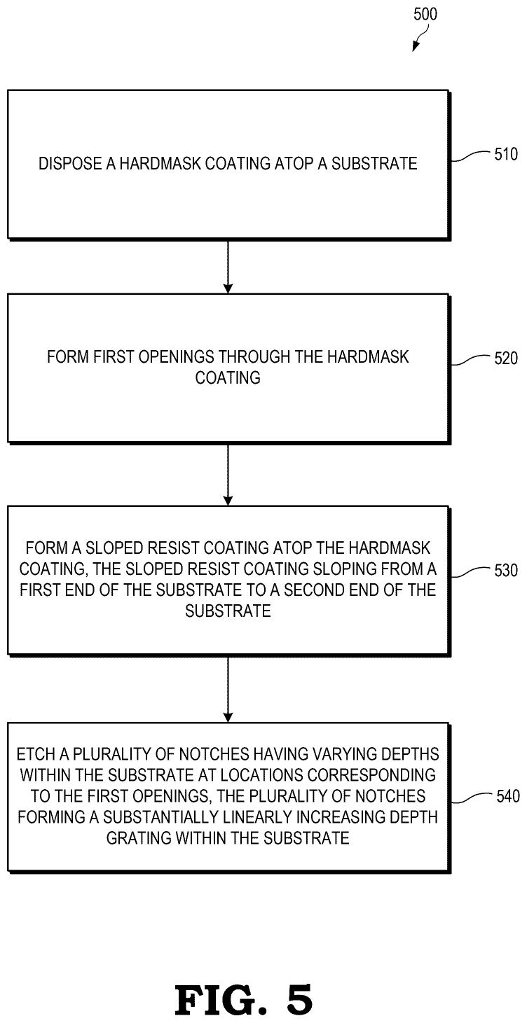

FIG. 4-5 shows a cross-sectional view of a structure 450 after another layer is disposed atop the structure 440 shown in FIG. 4-4. A low contrast resist coating 452 is disposed atop the structure shown in FIG. 4-4. In some embodiments, the low contrast resist coating is disposed atop an entirety of the structure shown in FIG. 4-4. As shown, the low contrast resist coating 452 is disposed over the blocks of hardmask coating 443 and deposited into the openings 442 through the hardmask coating 414 shown in FIG. 4-4. At this step of fabrication of the linearly increasing depth grating 201, the low contrast resist coating 452 is substantially planar (e.g. +/−10%), with variations possible due to manufacturing discrepancies.

FIG. 4-6 illustrates a cross-sectional view 460 after lithography is performed on the structure 450 shown in FIG. 4-5. In some embodiments, grayscale lithography is performed on the structure 450 shown in FIG. 4-5. The grayscale lithography is less intense at a first end, starting over a left-most block of hardmask coating 443, and linearly increases in intensity as a function of distance from the left-most block of hardmask coating 443. Note that left and right are arbitrary and are for example only, with some embodiments reversing the intensity of the grayscale lithography. The grayscale lithography results in the low contrast resist coating 452 shown in FIG. 4-5 being modified after development from being planar to instead be a ramped low contrast resist coating 462, ramped downward from a left-most block of hardmask coating 443 to a right edge of the structure shown in FIG. 4-6. The slope patterning of the ramped low contrast resist coating 462 defines a slope of the linearly increasing depth grating 201. Thus, only two levels of lithography are used to produce ramped low contrast resist coating 462: the lithography of FIG. 4-3 and the grayscale lithography of FIG. 4-6.

FIG. 4-7 shows a cross-sectional view 470 after etching is performed on the structure shown in FIG. 4-6. In some embodiments, the etching is a dry etching, although in some embodiments this etching is wet etching. The etching results in the ramped low contrast resist coating 462 being removed from the structure shown in FIG. 4-6. The etching also produces a plurality of varying depth notches 472 into the substrate 412, which form the linearly increasing depth grating 201. As shown, the shallowest of the plurality of varying depth notches 472 is disposed proximate to the left side of the substrate 412 and the deepest of the plurality of varying depth notches 472 is disposed proximate to the right side of the substrate 412. The plurality of varying depth notches 472 between the shallowest and the deepest notches 472 linearly increase in depth from the left side of the substrate 412 to the right side of the substrate 412. Although the plurality of varying depth notches 472 is shown as increasing in depth from the left side of the substrate 412, in some embodiments the plurality of varying depth notches 472 increases in depth from the right side of the substrate 412.

FIG. 4-8 shows a cross-sectional view 480 after etching is performed on the structure shown in FIG. 4-7. In some embodiments, the etching is a dry etching, although in some embodiments the etching is wet etching. The etching removes the hardmask coating 414, thereby removing the last of the coatings shown in FIGS. 4-1-4-7 that were disposed atop the substrate 412 to form the plurality of varying depth notches 472.

FIG. 5 shows a method flow of an example method 500 to form the linearly increasing depth grating shown in FIGS. 2-4, in accordance with some embodiments. Method 500 begins with block 510. At block 510, the hardmask coating 414 is disposed atop the substrate 412. In some embodiments, the substrate 412 of the method 500 is a silicon dioxide-based material, such as quartz.

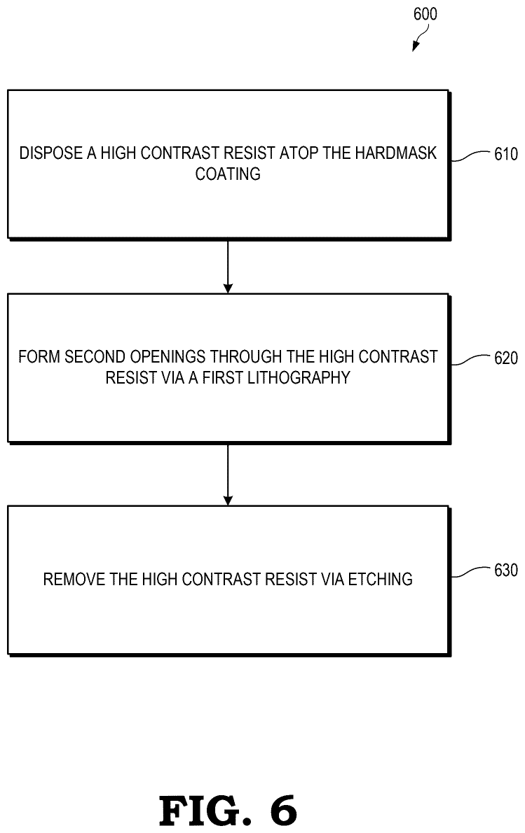

At block 520 first openings, such as the openings 442, are formed through the hardmask coating 414. As will be discussed below with respect to FIG. 6, a method 600 can be used to form the openings 442 through the hardmask coating 414.

At block 530 the ramped low contrast resist coating 462 is formed atop the hardmask coating 414. The ramped low contrast resist coating 462 is formed via grayscale lithography that exposes the low contrast resist coating 462 with a spatially modulated dose of lithography to form the ramped low contrast resist coating 462. Block 530 uses a spatially modulated dose of grayscale lithography that linearly increases in intensity from a first end of the low contrast resist coating 452 to a second end of the low contrast resist coating 452. Block 530 modifies the low contrast resist coating 452 shown in FIG. 4-5 from being planar to instead be a ramped low contrast resist coating 462, ramped downward from the left-most block of hardmask coating 443 to the right edge of the structure shown in FIG. 4-6. As shown in FIG. 4-6, the ramped low contrast resist coating 462 ramps from a first end of the substrate 412 to a second end of the substrate 412.

At block 540 the plurality of varying depth notches 472 having varying depths within the substrate 412 are etched at locations corresponding to the openings 442. Block 540 forms the plurality of varying depth notches 472 that form the substantially linearly increasing depth grating 201 within the substrate 412. Thus, an entirety of the linearly increasing depth grating 201 is fabricated via a single fabrication process of the method 500 instead of being fabricated via multiple fabrication steps for each step, respectively, of the typical stepped grating.

FIG. 6 illustrates a method flow of an example intermediate method 600 to form the openings 442 through the hardmask coating prior 414 prior to forming the linearly increasing depth grating 201 with the method shown in FIG. 5. Method 600 begins with block 610. At block 610, the high contrast resist 422 is disposed atop the hardmask coating 414.

At block 620, second openings, such as openings 432, are formed through the high contrast resist 422 via first lithography. In some embodiments, block 620 applies one of one of E beam lithography, Deep Ultraviolet (DUV) lithography, and nanoimprint lithography to the high contrast resist 422. The result of this lithography is that block 620 forms the openings 432 through the high contrast resist 422, shown in FIG. 4-3.

At block 630, the high contrast resist 422 is removed via etching. Block 630 also forms, via this etching, the openings 442 through the hardmask coating 414, shown in FIG. 4-4. Block 630 proceeds to block 530 to form the ramped low contrast resist coating 462 atop the hardmask coating 414.

In some embodiments, certain aspects of the techniques described above may be implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

1. A method comprising:
disposing a hardmask coating atop a substrate;
forming first openings through the hardmask coating;
forming a ramped resist coating atop the hardmask coating, the ramped resist coating sloping from a first end of the substrate to a second end of the substrate; and
etching a plurality of varying depth notches having varying depths within the substrate at locations corresponding to the first openings, the plurality of varying depth notches forming a substantially linearly increasing depth grating within the substrate.

2. The method of claim 1, wherein the forming the first openings comprises:
disposing a high contrast resist atop the hardmask coating;
forming second openings through the high contrast resist via a first lithography; and
removing the high contrast resist via etching.

3. The method of any one of claim 2, wherein the first lithography comprises one of E beam lithography, Deep Ultraviolet (DUV) lithography, and nanoimprint lithography.

4. The method of claim 1, wherein the ramped resist coating is a low contrast resist coating and forming the ramped resist coating comprises:
applying a second lithography to the low contrast resist coating.

5. The method of claim 4, wherein the second lithography is a grayscale lithography that exposes the low contrast resist coating with a spatially modulated dose of lithography to form the ramped resist coating, the spatially modulated dose linearly increasing in dosage from a first end of the low contrast resist coating to a second end of the low contrast resist coating.

6. The method of claim 1, further comprising:
removing the hardmask coating via etching.

7. The method of claim 1, wherein the substrate is a silicon dioxide-based material.

8. A method comprising:
disposing a hardmask coating atop a substrate;
forming first openings through the hardmask coating; and
etching a plurality of varying depth notches having varying depths within the substrate at locations corresponding to the first openings, the plurality of varying depth notches forming a substantially linearly increasing depth grating within the substrate.

9. The method of claim 8, wherein the forming the first openings comprises:
disposing a high contrast resist atop the hardmask coating;
forming second openings through the high contrast resist via a first lithography; and
removing the high contrast resist via etching.

10. The method of any one of claim 9, wherein the first lithography comprises one of E beam lithography, Deep Ultraviolet (DUV) lithography, and nanoimprint lithography.

11. The method of claim 8, further comprising:
forming a ramped low-contrast resist coating atop the hardmask coating, the ramped resist coating sloping from a first end of the substrate to a second end of the substrate, by applying a second lithography to a low contrast resist coating to form the ramped low-contrast resist coating.

12. The method of claim 11, wherein the second lithography is a grayscale lithography that exposes the low-contrast resist coating with a spatially modulated dose of lithography to form the ramped low-contrast resist coating, the spatially modulated dose linearly increasing in dosage from a first end of the low-contrast resist coating to a second end of the low contrast resist coating.

13. The method of claim 8, further comprising:
removing the hardmask coating via etching.

14. The method of claim 8, wherein the substrate is a silicon dioxide-based material.

15. A grating structure comprising:
a substantially linearly increasing depth grating disposed within a substrate, the substantially linearly increasing depth grating comprising a plurality of varying depth notches within the substrate.

16. The grating structure according to claim 15, wherein the substantially linearly increasing depth grating is formed via a method comprising:
disposing a hardmask coating atop a substrate;
forming first openings through the hardmask coating;
forming a ramped resist coating atop the hardmask coating, the ramped resist coating sloping from a first end of the substrate to a second end of the substrate; and
etching a plurality of varying depth notches having varying depths within the substrate at locations corresponding to the first openings, the plurality of varying depth notches forming a substantially linearly increasing depth grating within the substrate.

17. The grating structure according to claim 16, wherein the forming the first openings comprises:
disposing a high contrast resist atop the hardmask coating;
forming second openings through the high contrast resist via a first lithography; and
removing the high contrast resist via etching.

18. The grating structure according to claim 16, wherein the ramped resist coating is a low contrast resist coating and the forming the ramped resist coating comprises:
applying a second lithography to the low contrast resist coating to form the ramped resist coating.

19. The grating structure according to claim 18, wherein the second lithography is a grayscale lithography that exposes the low contrast resist coating with a spatially modulated dose of lithography to form the ramped resist coating, the spatially modulated dose linearly increasing in dosage from a first end of the low contrast resist coating to a second end of the low contrast resist coating.

20. The grating structure according to claim 16, wherein the method further comprises:
removing the hardmask coating via etching.

21. The grating structure according to claim 15, wherein the substrate is a silicon dioxide-based material.
